(19) United States
(12) Patent Application Publication
(10) Pub. No.: US 2022/0238160 A1
(43) Pub. Date: Jul. 28, 2022

(54) OPERATION METHOD OF MEMORY DEVICE

(71) Applicant: MACRONIX INTERNATIONAL CO., LTD., Hsinchu (TW)

(72) Inventors: Guan-Wei WU, Zhubei City (TW); Yao-Wen CHANG, Zhubei City (TW); I-Chen YANG, Miaoli County (TW)

(21) Appl. No.: 17/158,035

(22) Filed: Jan. 26, 2021

(51) Int. Cl. G11C 16/10; G11C 16/26; G11C 16/30; G11C 16/08; G11C 16/24; G11C 16/34; G11C 16/04

(52) U.S. Cl. CPC G11C 16/10; G11C 16/26; G11C 16/30; G11C 16/0433; G11C 16/24; G11C 16/3454; G11C 16/08

(57) ABSTRACT

An operation method of a memory device is provided. The memory device includes P-type well, a common source line, a memory array, a plurality of word lines, and a serial selection line, a ground selection line, and at least one bit line. The word lines include a first word line and a second word line that are programmed and not adjacent to each other. The operation method includes the following steps. A read voltage is applied to a selected word line. A pass voltage is applied to unselected word lines, and the read voltage is less than the pass voltage. During a period when the pass voltage ramps down to a lower level before the end of a read operation, a channel potential of the memory string is down-coupled, a hole current is injected to flow from the P-type well to the memory string to neutralize the channel potential.

### BACKGROUND OF THE INVENTION

### Field of the Invention

The invention relates in general to an operation method of a memory device.

### Description of the Related Art

In a memory device, the read operation of a word line will increase the threshold voltage of an adjacent word line, which is called read disturbance.

For both 2D and 3D NAND flash memory, a plurality of dummy word lines has been used in the NAND string for different purposes. With the development of the size and density of the array, additional dummy word lines have been incorporated in the NAND string to reduce undesirable disturbance of the word lines on the edges. In the absence of dummy word lines, the edge word lines of the NAND string are located in high electric field space, so that they are easily subjected to the disturbance caused by Fowler-Nordheim (FN) tunneling or hot carrier injection.

In addition, as technology nodes continue to shrink and the demand for multiple bits per memory cell increases, the number of programming shots has been greatly increased, which makes the memory cell transistor on the word line almost unavoidable from hot carrier injection and related read disturbances. As such, the issue needs to be further improved.

### SUMMARY OF THE INVENTION

The present invention is directed to an operation method of a memory device to prevent the hot carrier injection and related read disturbances so that the read accuracy of adjacent word lines will not be affected.

According to one aspect of the present invention, an operation method of a memory device is provided. The memory device includes a P-type well, a common source line, a memory array, a plurality of word lines, and a serial selection line, a ground selection line, and at least one bit line, wherein the word lines are connected to a memory string in a memory array, and the word lines are arranged between the serial selection line and the ground selection line. The memory string is connected between the bit line and the common source line. The word lines include a first word line and a second word line that are programmed and not adjacent to each other. The operation method includes the following steps. A read voltage is applied to a selected word line. A pass voltage is applied to unselected word lines, and the read voltage is less than the pass voltage. Before an end of a read operation, a ground selection transistor on the ground selection line is turned off in advance, so that a gate voltage of the ground selection transistor drops from the pass voltage to a lower level.

According to one aspect of the present invention, an operation method of a memory device is provided. The memory device includes a memory string having a down-coupled channel potential. The operation method includes the following steps. A read voltage is applied to a selected word line. A pass voltage is applied to unselected word lines, and the read voltage is less than the pass voltage. Before an end of a read operation, a ground selection transistor is turned off in advance, so that a gate voltage of the ground selection transistor drops from the pass voltage to a lower level.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a schematic diagram of a memory device according to an embodiment of the invention.

FIG. 2 is a schematic diagram of a voltage waveform of the memory device during a read operation.

FIG. 3 is a schematic diagram showing the down-coupling of the channel potential between the first word line and the second word line before the end of the read operation.

FIG. 4 is a schematic diagram of an operation method of a memory device according to an embodiment of the invention.

FIG. 5 is a schematic diagram of a voltage waveform of the memory device during a read operation according to an embodiment of the invention.

FIG. 6 is a schematic diagram showing that the channel potential before the end of the read operation is not coupled down between the first word line and the second line.

FIG. 7 is a schematic diagram of a voltage waveform of the memory device during a read operation according to another embodiment of the invention.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION OF THE INVENTION

Details are given in the non-limiting embodiments below. It should be noted that the embodiments are illustrative examples and are not to be construed as limitations to the claimed scope of the present invention. The same/similar denotations are used to represent the same/similar components in the description below.

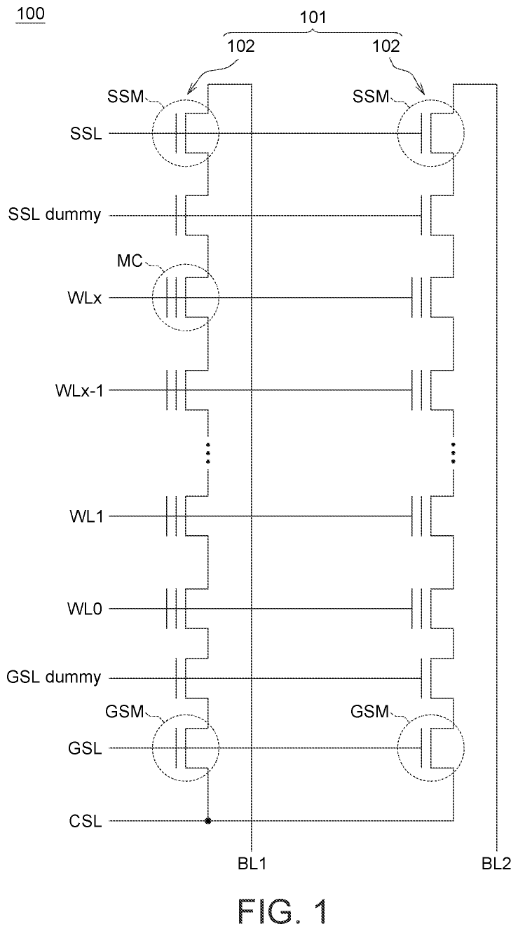

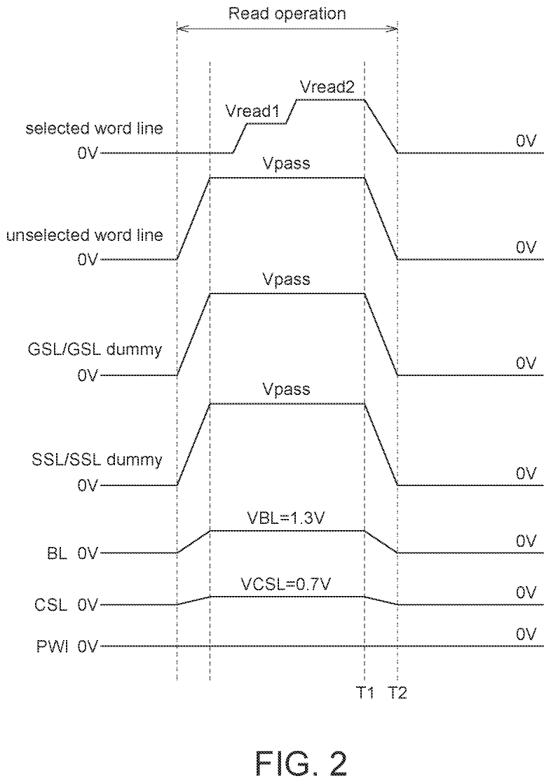

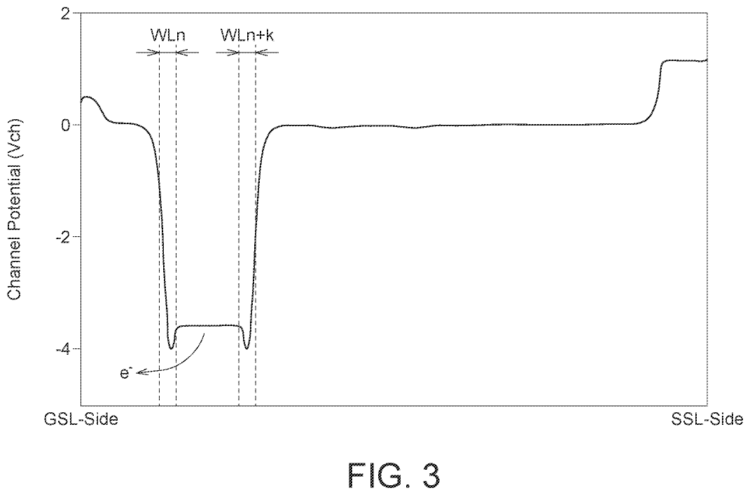

Please refer to FIGS. 1, 2 and 3. FIG. 1 is a schematic diagram of a memory device 100 according to an embodiment of the present invention, and FIG. 2 shows a voltage waveform of the memory device 100 during a read operation. FIG. 3 is a schematic diagram showing the down-coupling of the channel potential Vch between the first word line WLn and the second word line WLn+k before the end of the read operation.

Referring to FIG. 1, according to an embodiment of the invention, the memory device 100 has multiple layers of word lines WL0 to WLx stacked in a vertical direction. The parallel strip-shaped serial selection line SSL and dummy SSL are arranged above the word line WLx, and the ground selection line GSL and dummy GSL are arranged below the word line WL0. The intersection of each of bit lines BL1, BL2 and the serial selection line SSL/dummy SSL is the serial selection transistor SSM, and the intersection of each of the bit lines BL1, BL2 and the ground selection line GSL/dummy GSL is the ground selection transistor GSM. A group of memory cells (MC) on the word lines WL0 to WLx are connected in series to the bit line BL1 to form a memory string 102, so that the memory string 102 is connected between the bit line BL1 and the common source line CSL. In addition, another group of memory cells on the word lines WL0 to WLx are connected in series to the bit line BL2 to form another memory string 102, so that the memory string 102 is connected between the bit line BL2 and the common source line CSL.

In other words, the memory string 102 is located between the P-type well and the bit line BL and includes a plurality of memory cells. The memory cell is, for example, a unit cell, a multiple-level cell, or a triple-level cell, etc., which is not limited in the present invention. Taking the triple-level cell as an example, the memory cell can be programmed into 8 states, which are erased state, A state, B state, C state, D state, E state, F state, and G state. The highest state is the G state, which has the highest threshold voltage. Among them, two non-adjacent memory cells in the memory string 102 can be programmed to be in the G state (the state of highest threshold voltage), and the remaining memory cells can be in the erased state. As shown in FIG. 3, the first word line WLn and the second word line WLn+k with a higher threshold voltage are not adjacent, where n is a positive integer, and k is a positive integer greater than 1, for example, any integer from 2 to 10. In an embodiment, a down-coupled channel potential Vch may be formed between the first word line WLn and the second word line WLn+k.

Before the memory string 102 performs a programming operation, the memory string 102 may perform an erase operation. The voltage of the erasing operation is, for example, the voltage applied to the substrate (P-type well) PWI via the local interconnection. The erasing voltage is, for example, −18V, and the voltages of the programming operation is, for example, the voltage applied to a selected word line and the pass voltage Vpass applied to an unselected word line via a wire. The pass voltage Vpass is smaller than the programming voltage applied to the gate of the selected word line, the pass voltage Vpass is, for example, 10V, and the programming voltage is, for example, 20V.

When electrons are injected from the bit line BL into a channel of the memory string 102 and flow to the gate of the selected word line due to a programming operation, the electrons are stored in the charge trapping layer to increase the threshold voltage of the gate.

Next, referring to FIGS. 2 and 3, selected the word line performs a read operation or a verification operation after programming. Before the end of the read operation or verification operation, during the period when the pass voltage Vpass on the unselected word line is ramped down to a lower level (for example, 0V), since there are memory cells with high threshold voltages on the two non-adjacent word lines WLn and WLn+k, when the selected word line is discharged, the down-coupled channel potential Vch (for example, −4V) is formed, hot carriers (electrons e−) can easily move to the gate of the adjacent word line through the down-coupled channel, thereby resulting in read disturbance problem on the adjacent word line WLn−1 and/or WLn+k+1.

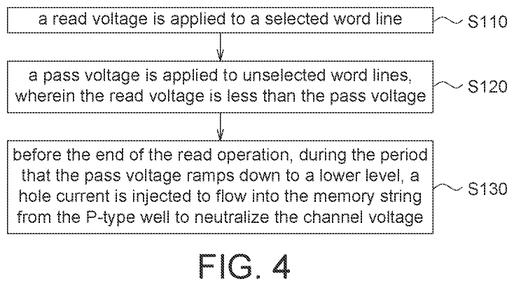

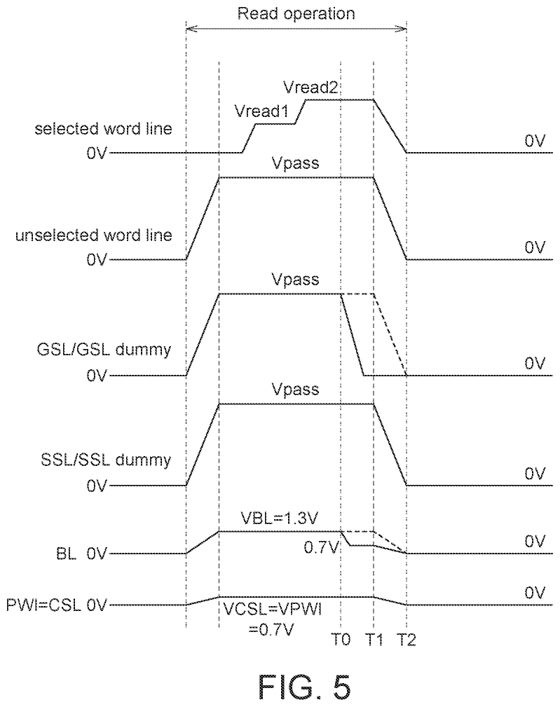

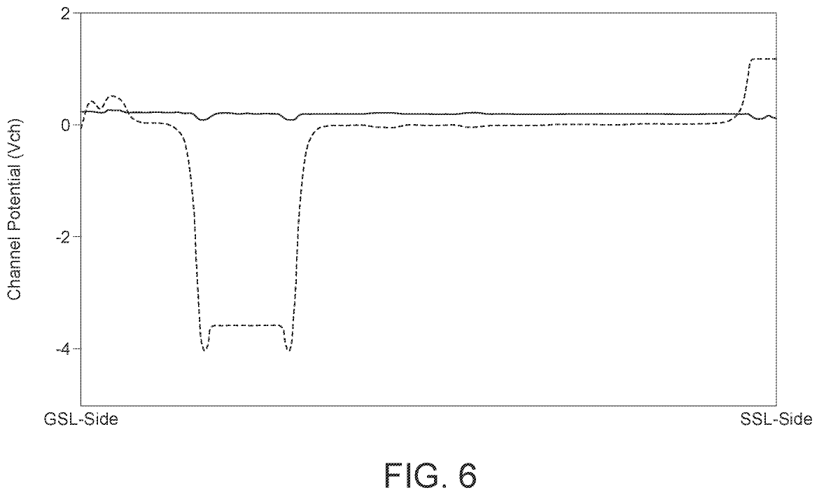

Please refer to FIGS. 4, 5, and 6. FIG. 4 is a schematic diagram of an operation method of the memory device 100 according to an embodiment of the invention, and FIG. 5 is a schematic diagram of the voltage waveform of the memory device 100 during the read operation according to an embodiment of the invention. FIG. 6 is a comparison diagram showing that the channel potential Vch before the end of the read operation is not down-coupled between the first word line and the second line and the down-coupling of the channel potential shown in the FIG. 3.

The operation method includes the following steps. In step S110, a read voltage Vread is applied to a selected word line. In step S120, a pass voltage Vpass is applied to unselected word lines, wherein the read voltage Vread is less than the pass voltage Vpass. In step S130, before the end of the read operation, during the period that the pass voltage Vpass ramps down to a lower level, a hole current is injected to flow into the memory string 102 from the P-type well to neutralize the channel potential Vch.

Next, referring to FIGS. 5 and 6, the step of injecting the hole current to flow into the memory string 102 from the P-type well is, for example, turning off the ground selection line GSL and dummy GSL, so that the gate voltage of the selection transistor drops from the pass voltage Vpass to 0V in advance, and the P-type well and the common source line CSL is maintained at 0.7V (VPWI=VCSL=0.7) during the read operation. That is, a potential of the P-type well is greater than a channel potential Vch between the first word line WLn and the second word line WLn+k. Therefore, the hole current can be injected into the memory string 102 through the ground selection transistor GSM to neutralize the down-coupled channel potential Vch. At this time, the gate voltage of the selection transistor on the serial selection line SSL is still maintained at the pass voltage Vpass, and does not ramp down to 0V until the end of the read operation. Therefore, in the present embodiment, the voltage of the ground selection line GSL can be ramped down to 0V during the period from T0 to T1 before the end of the read operation, thus allowing hole current to be injected into the memory string 102 from the P-type well, so that the channel potential Vch of the memory string 102 during the period from T1 to T2 would not be down-coupled between the first word line WLn and the second word line WLn+k, thus preventing hot carriers (electrons) from easily passing through the down-coupled channel and moving to the gate of the adjacent word lines, and causing read disturbance of the adjacent word lines.

In addition, referring to FIG. 5, the bit line BL maintains at a precharge voltage (for example, 1.3V) during the read operation, and the voltage VBL of the bit line BL during the period from T0 to T1 before the pass voltage Vpass ramps down, drops from the precharge voltage to a lower level (for example, 0.7V). In addition, the common source line CSL is maintained at 0.7V during the read operation, and the common source line CSL is coupled to the P-type well to form an equipotential level during the period from T0 to T1 before the pass voltage ramps down to the lower level, so that the electronic holes in the P-type well can easily cross the energy barrier of the ground selection transistor GSM (GSL/GSL Dummy) and inject into the memory string 102. In the present embodiment, in order to keep electronic holes in the channels of the memory string 102, the voltage of the bit line BL drops from the precharge voltage 1.3V to 0.7V during the period from T0 to T1 before the pass voltage Vpass ramps down so that the voltage of the bit line BL is equipotential to the voltages VCSL/VPWI of the common source line CSL and the P-type well. In such way, the injected electronic holes would not leak into bit lines BL through SSL and SSL Dummy.

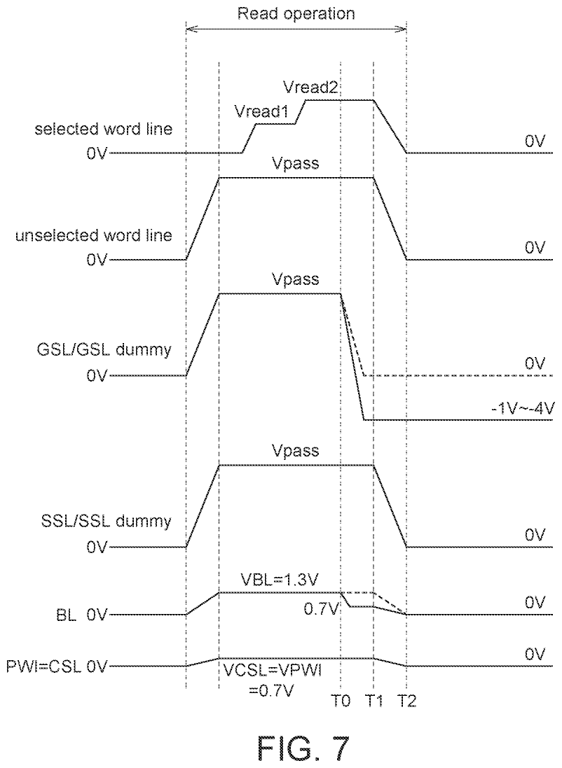

Please refer to FIG. 7, which shows a schematic diagram of a voltage waveform of a memory device 100 during a read operation according to another embodiment of the invention. In another embodiment, the step of injecting hole currents into the memory string 102 from the P-type well is, for example, applying a negative voltage to the selection transistor on the ground selection line GSL (GSL/GSL Dummy), so that the gate voltage of the selection transistor drops from the pass voltage Vpass to a lower level in advance, for example, −1V to −4V. Therefore, the voltage of the ground selection line GSL drops to a lower level (less than 0V) during the period from T0 to T1 before the end of the read operation, so that more hole currents can pass through the ground selection transistor GSM and inject into the memory string 102 to neutralize the down-coupled channel potential Vch.

In addition, referring to FIG. 7, the bit line BL maintains a precharge voltage (for example, 1.3V) during the read operation, and the voltage of the bit line BL during the period from T0 to T1 before the pass voltage Vpass ramps down, drops from the precharge voltage to a lower level (for example, 0.7V). In addition, the common source line CSL is maintained at 0.7V during the read operation, and the common source line CSL is coupled to the P-type well to form an equipotential level, so that the electronic holes in the P-type well can easily cross the energy barrier of the ground selection transistor GSM and inject into the memory string 102. In the present embodiment, in order to keep electronic holes in the channels of the memory string 102, the voltage of the bit line BL drops from the precharge voltage 1.3V to 0.7V during the period from T0 to T1 before the pass voltage Vpass ramps down so that the voltage of the bit line BL is equipotential to the voltages of the common source line CSL and the P-type well. In such way, the injected electronic holes would not leak into bit line BL through SSL and SSL Dummy.

In an embodiment, the read operation method of FIG. 4 can be applied to a normal read operation, and can also be applied to a program-verify operation, all of which are intended to be protected in the scope of the present invention. In an embodiment not shown, the memory device 100 may include a controller coupled to the memory array 101 (see FIG. 1). The controller can execute the operation method described in the foregoing embodiment, which is not repeated here.

The operation method of the memory device described in the above embodiment of the invention can effectively suppress the read disturbance of adjacent word lines, so as to correctly read the output data, and thereby the read accuracy of the word lines is increased.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An operation method of a memory device, the memory device comprising a P-type well, a common source line, a memory array, a plurality of word lines, and a serial selection line, a ground selection line, and at least one bit line, wherein the word lines are connected to a memory string in the memory array, and the word lines are arranged between the serial selection line and the ground selection line, the memory string is connected between the bit line and the common source line, and the word lines include a first word line and a second word line that are programmed and not adjacent to each other, the operation method comprising:
applying a read voltage to a selected word line;
applying a pass voltage to unselected word lines, and the read voltage being less than the pass voltage; and
before an end of a read operation, a ground selection transistor on the ground selection line is turned off in advance, so that a gate voltage of the ground selection transistor drops from the pass voltage to a lower level.

2. The method according to claim 1, wherein when the gate voltage of the ground selection transistor drops from the pass voltage to the lower level, a potential of the P-type well is set greater than a channel potential between the first word line and the second word line, so that a hole current is injected into the memory string from the P-type well to neutralize the channel potential.

3. The method according to claim 2, wherein the gate voltage of the ground selection transistor dropping from the pass voltage to the lower level is performed by applying a negative voltage to the ground selection transistor on the ground selection line, so that the gate voltage of the ground selection transistor drops from the pass voltage to the lower level less than 0V.

4. The method according to claim 1, wherein a gate voltage of a selection transistor on the serial selection line is still maintained at the pass voltage and does not ramp down to 0V until the end of the read operation.

5. The method according to claim 1, wherein the common source line is maintained at 0.7V during the read operation, and the common source line is coupled to the P-type well to form an equipotential level during a period before the pass voltage ramps down to the lower level.

6. The method according to claim 1, wherein the bit line maintains at a precharge voltage during the read operation, and a voltage of the bit line during a period before the pass voltage ramps down, drops from the precharge voltage to a lower level.

7. The method according to claim 6, wherein during the period before the pass voltage ramps down to the lower level, the method further comprises forming an equipotential level to the bit line and the common source line, and the common source line is coupled to the P-type well.

8. The method according to claim 1, wherein the operation method is applied to a normal read operation or a program-verify operation.

9. An operation method of a memory device, the memory device comprising a memory string having a down-coupled channel potential, the operation method comprising:
applying a read voltage to a selected word line;
applying a pass voltage to unselected word lines, and the read voltage being less than the pass voltage; and
before an end of a read operation, a ground selection transistor is turned off in advance, so that a gate voltage of the ground selection transistor drops from the pass voltage to a lower level.

10. The method according to claim 9, wherein when the gate voltage of the ground selection transistor drops from the pass voltage to the lower level, a potential of a P-type well is set greater than the channel potential, so that a hole current is injected into the memory string from the P-type well to neutralize the channel potential.

11. The method according to claim 9, wherein the gate voltage of the ground selection transistor dropping from the pass voltage to the lower level is performed by applying a negative voltage to the ground selection transistor, so that the gate voltage of the ground selection transistor drops from the pass voltage to the lower level less than 0V.
